(19) United States
(12) Patent Application Publication
(10) Pub. No.: US 2026/0082168 A1
(43) Pub. Date: Mar. 19, 2026

(54) IMPEDANCE DETECTION AND CURRENT ADJUSTMENT FOR AUDIO DEVICES

(71) Applicant: Shure Acquisition Holdings, Inc., Niles, IL (US)

(72) Inventors: Myzil Elroy Boyce, Naperville, IL (US); Dave Verlee, Morton Grove, IL (US); Ross Penniman, Morton Grove, IL (US)

(73) Assignee: Shure Acquisition Holdings, Inc., Niles, IL (US)

(21) Appl. No.: 19/325,145

(22) Filed: Sep. 10, 2025

Related U.S. Application Data
(60) Provisional application No. 63/694,576, filed on Sep. 13, 2024.

(51) Int. Cl. H04R 29/00; G01R 27/26; H04R 3/04

(52) U.S. Cl. CPC H04R 29/007; G01R 27/26; H04R 3/04

(57) ABSTRACT

The disclosure relates to audio systems and methods with load impedance detection and current adjustment. An audio system (e.g., personal stage monitoring (PSM) receiver) may include an impedance detector that detects impedance of the connected load, and a current adjuster that provides an adjustable available current to the connected load based on the detected impedance. The current adjuster may be amplifier(s) (e.g., buffers) connected in parallel between an audio amplifier of the PSM receiver and the connected device. The current adjuster may adaptively adjust available current that may be provided/delivered to the connected device (e.g., when the connected device is a low-impedance load) and disable additional current made available to the connected device when the connected load is a high-impedance load. The impedance detector may be configured to measure the impedance of an unknown load in real time to facilitate the adaptive availability of the current by the current adjuster.

### CROSS REFERENCE TO RELATED APPLICATIONS

This patent application claims priority to, and the benefit of, U.S. Provisional Patent Application No. 63/694,576, filed Sep. 13, 2024, entitled “Impedance Detection and Current Adjustment For Audio Devices,” which is incorporated herein by reference in its entirety.

### TECHNICAL FIELD

Aspects of the disclosure relate to impedance detection and current adjustment for audio systems, such as detection of impedances of devices (e.g., audio input and/or output devices) connected to the audio device and the adjustment of current based on the detected impedance load of the connected device(s).

### BACKGROUND

Live performance environments, such as music concerts, theatrical productions, and other events, require enabling performers to hear themselves and other performers clearly in order to deliver their best performance. An audio system may include a monitoring system, which may be referred to as in-car-monitoring (IEM) system or personal stage/stereo monitoring (PSM) system, to provide performers with monitoring feedback using, for example, monitoring speakers on stage or in-car monitors (IEMs). Feedback to the performers allows performers to hear themselves and other performers more clearly, even in noisy environments. Monitoring systems may include a transmitter and receiver, such as a battery-powered bodypack receiver worn by the user, where the IEMs are connected to (e.g., plugged into) the bodypack.

Given the limited (e.g., battery) power source of the receiver, the management of the power consumption may be used to extend the runtime of the receiver. The impedances of the existing IEMs vary widely and are often very low (e.g., 10 ohms or less). The lower impedance may result from a high number of drivers placed in parallel, as loads placed in parallel have a lower total impedance than any of the individual component loads. These low impedances can cause high electrical current draw from the receiver's output amplifier and result in low efficiency and losses. The result can lead to audible distortion in certain frequency ranges at high volume levels.

### SUMMARY

Aspects of the disclosure provide effective, scalable, and reliable technical solutions that address and overcome the problems associated with operation of complex audio systems, including the operation of monitoring systems (that are compatible with various IEMs having varying impedance loads).

An example audio system may include a chain of discrete subcomponents, each configured to perform a specific audio processing functionality. For example, the subcomponents may include microphones, receivers, mixers, amplifiers, speakers, a PSM system, musical instruments, general-purpose computing devices, etc.

A monitoring system may include a transmitter (Tx) and a receiver (Rx), where the transmitter may transmit audio data to the receiver to provide performers with monitoring feedback. The transmission may be wireless or via one or more wired connections. The receiver may be one or more monitoring speakers on stage, or a portable device worn by the performer that may include an audio output, such as in-car monitors (IEMs). Feedback to the performers may allow performers to hear themselves, instruments, audio tracks, and/or other performers more clearly, even in noisy environments. The receiver may include an impedance detection device (e.g., digital signal processor) configured to detect the impedance of the connected load (e.g., connected IEM), and a current adjustment device (current adjuster) configured to selectively provide current to the connected load based on the detected impedance. The current adjuster may be one or more amplifiers (e.g., buffers, such as a “unity gain” buffer or amplifier) connected in parallel between the audio amplifier of the receiver and the connected device. The current adjuster may adaptively provide current, such as when the connected device is a low-impedance load. The adaptive application of the current by the current adjuster improves efficiency of the receiver by disabling the application of the (additional) current when the connected load is a high-impedance load. The impedance detection device (also referred to as impedance detector) may be configured to measure the impedance of an unknown load in real time to facilitate the adaptative application of the current by the current adjuster.

Although aspects are described with respect to monitoring systems, and more specifically to the receiver of the monitoring system having a selectably connected impedance load (e.g., IEM), aspects are applicable to other devices, including those with limited power supply capabilities (e.g., battery powered, USB powered, etc.), in which components with varying impedance loads are connectable.

### BRIEF DESCRIPTION OF THE DRAWINGS

The present disclosure is illustrated by way of example and not limited in the accompanying figures in which like reference numerals indicate similar elements and in which:

FIG. 1 shows an audio system according to one or more exemplary embodiments.

FIG. 2 shows an audio system according to one or more exemplary embodiments.

FIG. 3 shows receiver of a monitoring system according to one or more exemplary embodiments.

FIG. 4 is a flowchart of an impedance detection and current adjustment method according to one or more exemplary embodiments.

FIGS. 5-7 are flowcharts that collectively show impedance detection and current adjustment methods according to one or more exemplary embodiments.

### DETAILED DESCRIPTION

In the following description of various illustrative embodiments, reference is made to the accompanying drawings, which form a part hereof, and in which is shown, by way of illustration, various embodiments in which aspects of the disclosure may be practiced. It is to be understood that other embodiments may be utilized, and structural and functional modifications may be made, without departing from the scope of the present disclosure. It is noted that various connections between elements are discussed in the following description. It is noted that these connections are general and, unless specified otherwise, may be direct or indirect, wired or wireless, and that the specification is not intended to be limiting in this respect.

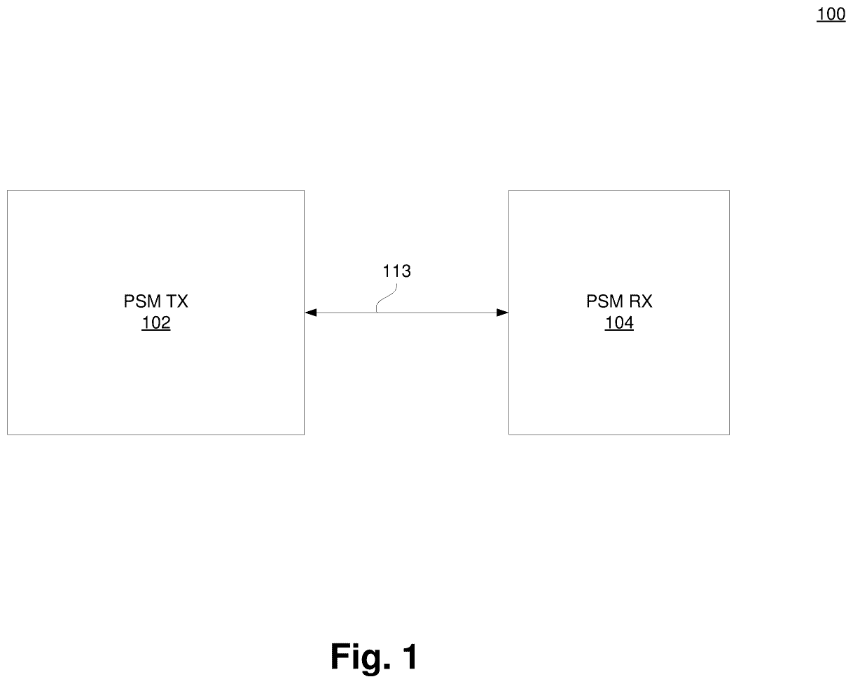

With reference to FIG. 1, an audio system 100 according to one or more exemplary embodiments may include a monitoring system, referred herein as a PSM system, having one or more PSM transmitters (PSM Tx) 102 and one or more PSM receivers (PSM Rx) 104. The PSM transmitter(s) 102 and PSM receiver(s) 104 may be configured to communicate with each other using one or more wireless and/or wired communication protocols via one or more connections 113. In one or more embodiments, the PSM transmitter(s) 102 and/or the PSM receiver(s) 104 may be configured as a transceiver that is configured to both transmit and receive information. The communications between the PSM transmitter(s) 102 and PSM receiver(s) 104 may be via one or more wireless and/or wired communication protocols.

The PSM transmitter(s) 102 may be located, for example, at a sound board or sound booth, and configured to transmit audio signals to the PSM receiver(s) 104. The PSM receiver(s) 104 may be located, for example, on the stage and associated with a monitor speaker, and/or may be implemented as a portable device that may be worn by the performer on stage. For example, the PSM receiver(s) 104 may be worn by the performer and may include a bodypack that is attached to the performer's belt or clothing and headphones (e.g. in-car monitors (IEMs) that fit snugly in the performer's ears). The headphones are responsible for delivering the audio signals directly to the performer's ears, allowing them to hear themselves, instruments, audio tracks, and/or other performers clearly on stage. In operation, the PSM transmitter(s) 102 and PSM receiver(s) 104 work together to provide a monitoring audio stream for the performer on stage. The sound engineer may provide mixed audio signals from an external mixing console or sound booth to the PSM transmitter(s) 102, which may then transmit the audio signals to the PSM receiver(s) 104 worn by the performer. The mixing console may be configured to perform personal mixing operations for one or more individual PSM receivers 104 to provide the performers with a personal mix of the audio. In one or more embodiments, the PSM transmitter(s) 102 may include an integrated mixer configured to perform one or more audio mixing and/or audio processing operations.

The PSM transmitter(s) 102 and the PSM receiver(s) 104 may be configured to transmit and/or receive signals using one or more communication protocols, such as an Institution of Electrical and Electronics Engineers (IEEE) 802.11 WIFI protocol, an IEEE 802.15.1 protocol (e.g., Bluetooth), an IEEE 802.15.4 protocol (e.g., Zigbee), or one or more other wireless personal area network (WPAN) protocols, a 3rd Generation Partnership Project (3GPP) cellular protocol, a local area network (LAN) protocol, a hypertext transfer protocol (HTTP), frequency modulation (FM) radio, infrared, one or more optical protocols, fiber optics, industrial, scientific, and medical (ISM) bands defined by the International Telecommunication Union (ITU) Radio Regulations (e.g., a 2.4 GHz-2.5 GHz band, a 5.75 GHz-5.875 GHz band, a 24 GHz-24.25 GHz band, and/or a 61 GHz-61.5 GHz band, etc.), a very high frequency (VHF) band (e.g., 30 MHz-300 MHz band) and/or via (e.g., one or more channels within) an ultra-high frequency (UHF) band (e.g., 300 MHz-3 GHz). The communication protocols that may be used are not limited to these example protocols.

The PSM system 100 may be implemented with one or more other audio subcomponents to form an audio system that includes a chain of discrete subcomponents, each configured to perform a specific audio processing functionality. For example, the subcomponents may include microphones, receivers, mixers, amplifiers, speakers, musical instruments, general-purpose computing devices, etc. The audio system may include one or more other electronic devices, such as a computing device (e.g., desktop computer, laptop computer), embedded computing device, mobile computing device (e.g., smartphone, tablet), and/or any other type of device.

As an example, audio system 100 may receive audio from one or more microphones and/or instruments, and process the audio via a receiver, mixer, and/or amplifier(s), prior to outputting the audio via one or more speakers. Various examples herein describe a PSM system, or an audio system 100 comprising a PSM system, that may be connected to one or more other audio devices (e.g., microphones, speakers, musical instruments and/or instrument outputs, transmitters, receivers, transceivers, computing devices, etc.). The PSM system may be flexibly configured to receive audio input from one or more audio sources (e.g. microphone(s), instrument(s), mixer(s), and/or audio track(s)) and provide monitoring feedback to the performer.

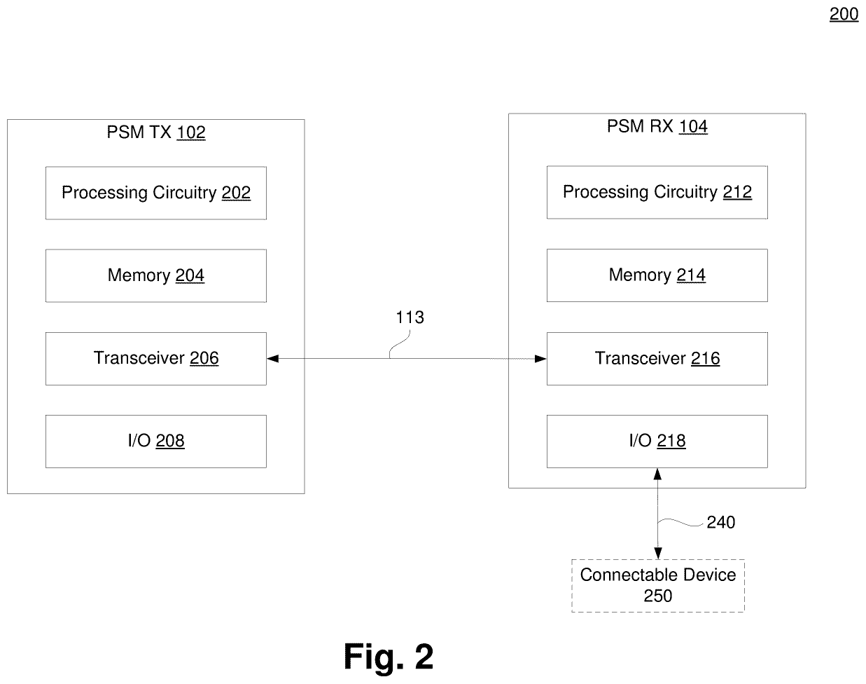

Audio system 200 according to one or more exemplary embodiments is illustrated in FIG. 2. The audio system 200 may be similar to audio system 100 and include a PSM system having one or more PSM transmitters (PSM Tx) 102 and one or more PSM receivers (PSM Rx) 104. Although embodiments are described with respect to a PSM system, embodiments of the disclosure are also applicable to other electronic devices having variable impedance loads. The PSM audio system of FIG. 2 may be implemented with one or more other audio subcomponents to form audio system 200. Such audio system 200 may include a complex configuration of interconnected discrete subcomponents, such as receivers, mixers, amplifiers, and/or other PSM system(s).

According to one or more exemplary embodiments, the PSM transmitter 102 may include processing circuitry 202 (e.g. one or more processors and/or circuitry), memory 204, transceiver(s) 206, and/or input/output (I/O) interface(s) 208. One or more data buses may interconnect the processing circuitry 202, the memory 204, transceiver(s) 206, and/or I/O interface(s) 208. The PSM transmitter 102 may be implemented using one or more integrated circuits (ICs), software, or a combination thereof, configured to operate as described herein. The processing circuitry 202 may include circuit(s) or processor(s), or a combination thereof. The memory 204 may comprise any memory, such as a random-access memory (RAM), a read-only memory (ROM), a flash memory, or any other electronically readable memory, or the like. The memory 204 may include one or more memory units.

In an exemplary embodiment, signals transmitted from and/or received by the PSM transmitter 102 may be encoded in one or more data units. For example, the processing circuitry 202 may be configured to generate data units, and process received data units, that conform to any suitable wired and/or wireless communication protocol. The transceiver 206 may be configured to send/receive signals to/from PSM receiver 104 using one or more communication protocols. For example, digital audio signals received by the PSM receiver(s) 104 may be audio signals contained in one or more radio frequency (RF) signals transmitted by the transceiver 206.

The communication protocols may be any wired communication protocol(s), wireless communication protocol(s), and/or one or more protocols corresponding to one or more layers in the Open Systems Interconnection (OSI) model. For example, the transceiver 206 may be configured to transmit and/or receive signals using an IEEE 802.11 WIFI protocol, an IEEE 802.15.1 protocol (e.g., Bluetooth), an IEEE 802.15.4 protocol (e.g., Zigbee), or one or more other wireless personal area network (WPAN) protocols, a 3GPP cellular protocol, a LAN protocol, HTTP), FM radio, infrared, one or more optical protocols, fiber optics, ISM bands defined by the International Telecommunication Union (ITU) Radio Regulations (e.g., a 2.4 GHz-2.5 GHz band, a 5.75 GHz-5.875 GHz band, a 24 GHz-24.25 GHz band, and/or a 61 GHz-61.5 GHz band, etc.), VHF band(s) (e.g., 30 MHz-300 MHz band) and/or via (e.g., one or more channels within) UHF band(s) (e.g., 300 MHz-3 GHz). The communication protocols that may be used are not limited to these example protocols. In one or more examples, the PSM transmitter(s) 102 and/or PSM receiver(s) 104 may communicate with one or more electronic devices (e.g., smartphones, tablet computers, remote control devices, etc.).

The processing circuitry 202 may be configured to perform one or more operations of the PSM transmitter 102, including controlling the operation of the PSM transmitter 102 and/or operation of one or more of its other components. For example, the processing circuitry 202 may process data and/or information associated with the operation of the PSM transmitter 102 and/or received by the PSM transmitter 102, and/or control the transceiver 206 to perform transmission and/or reception operations. The processing circuitry 202 may execute machine readable instructions stored in memory 204 to perform one or more operations of the PSM transmitter 102. As described above, the signals received and/or output by the PSM transmitter 102 (e.g., via the transceiver 206 and/or I/O interface 208) may be encoded in one or more data units in one or more embodiments. For example, the processing circuitry 202 may be configured to generate data units, and process received data units, that conform to any suitable wired and/or wireless communication protocol.

The processing circuitry 202 may be configured to perform one or more audio mixing operations, digital signal processing (DSP), and/or other signal processing on the audio signals received (e.g. via I/O interface 208) to generate processed audio data. The processed audio data may provide a customized mix of audio signals, which may then be provided to the PSM transmitter 102 to be transmitted to the PSM receiver 104 (using the transceiver 206). Such a configuration may provide an audio system with personal mixing for one or more performers. The mixing operations may be performed in the analog or digital domains. If multiple mixing operations are performed, one or more operations may be performed in the analog domain while one or more other operations may be performed in the digital domain.

In an exemplary embodiment, the processing circuitry 202 may be configured to perform one or more mixing operations using machine learning (ML), such as using one or more ML models to adjust (e.g. optimize) mixing parameters to control the mixing operations of the processing circuitry 202. The ML model may support a generative adversarial network, a bidirectional generative adversarial network, an adversarial autoencoder, or an equivalent thereof. Additionally, or alternatively, the ML model may be a convolutional neural network, a recurrent neural network, a recursive neural network, a long short-term memory (LSTM), a gated recurrent unit (GRU), an unsupervised pretrained network, a space invariant artificial neural network, or any equivalent thereof. The ML model may be trained based on input data and/or output data of the PSM transmitter 102, PSM receiver 104, one or more other components of the audio system, and/or one or more other devices in communication with the audio system. The ML model may be trained using different training techniques, such as supervised training, unsupervised training, semi-supervised training back propagation, transfer learning, stochastic gradient descent, learning rate decay, dropout, max pooling, batch normalization, and/or any equivalent deep learning technique.

In one or more exemplary embodiments, the personal mixing operations may include the adjustment of audio levels, panning, equalization (EQ), dynamic EQ, compression, multiband compression, summing, filtering, noise reduction, reverb, gain, delay, gating, expansion, de-essing, ducking, saturation, harmonic distortion, one or more modulation effects, sidechaining, adjustments to one or more other audio parameters, and/or one or more other audio processing operations.

Panning may include the process of placing audio elements in the stereo field, so that they appear to come from a particular location in the audio spectrum. For example, by adjusting the left-right balance of a signal, panning may create a sense of space and dimensionality in a mix. Equalization (EQ) may include the process of adjusting the frequency balance of audio tracks to improve balance and/or clarity. Equalization may include cutting or boosting specific frequency ranges to remove unwanted frequencies or enhance desired ones, and/or may be used to achieve a desired tone or timbre. Dynamic EQ may include adjusting the gain of certain frequency bands based on the input level of the audio signal, and may be useful in controlling harsh frequencies or taming certain resonances. Compression may include the process of reducing the dynamic range of audio tracks, making loud sounds quieter and quiet sounds louder. By reducing the difference between the loudest and softest parts of a track, compression may provide a more consistent and controlled audio. Multiband Compression is similar to compression, but instead of applying a single level reduction to the entire audio signal, it applies different levels of compression to different frequency bands. Multiband compression may be used to balance out a mix that has a lot of frequency imbalances. Summing may include adding together two or more audio signals to create a single output signal. The summing of audio signals may preserve the relative volume levels and stereo placement. Filtering may include the process of removing or attenuating certain frequencies in an audio signal, and may be used to remove unwanted noise and/or resonances, and/or to shape the tone of an audio signal. Noise reduction may include removing unwanted noise from an audio signal, such as removing hiss, hum, and/or other types of noise that may degrade the audio quality. Reverb may include simulating an acoustic environment in which an audio signal was recorded, and may be used to add space, depth, and/or natural reverberation to an audio signal, and/or to create a sense of continuity between different parts of a mix. Gain may include adjusting the overall level of an audio signal, and may be used to balance levels of different audio tracks in a mix, and/or to increase or decrease the overall loudness of the audio track. Delay adjustments may include the introduction of a time delay between an audio signal and its output, and/or the introduction of echoes and/or repeats. Delay may be used to create stereo width and/or to create rhythmic effects. Gating may include the attenuating of an audio signal when it falls below a certain level, and may be used to remove unwanted noise and/or in controlling the decay of certain sounds. Expansion may be the opposite of compression, where instead of reducing the dynamic range of an audio signal, expansion increases it. Expansion may be used to increase the life and energy to a mix. De-essing may include the process of reducing the level of harsh sibilant sounds in an audio signal, such as “s” and “t” sounds. De-essing may make a mixed sound less harsh and more pleasant to listen to. Ducking may include the reduction of the level of one audio signal when another audio signal is present. This can be useful in making a mixed sound more cohesive and reducing clashes between different tracks. Saturation may include adding harmonic distortion to an audio signal, which may be used to add warmth and character to a mix. Harmonic Distortion may include adding distortion to an audio signal to create new harmonic content. Modulation Effects may include effects (e.g. chorus, flanger, and phaser) that modulate certain aspects of an audio signal, such as pitch, frequency, and/or amplitude. Side chaining may include using the level of one or more audio signals to control the processing of one or more other audio signals. A side chain input may be used, for example, on a compressor or other processor, which allows the level of the separate audio signal(s) to control the amount of processing applied to the other audio signal(s). For example, in a music mix, a side chain input can be used to trigger a compressor on a bass track using the kick drum track as the side chain input. This may cause the bass to be compressed every time the kick drum hits, which can help to create a more cohesive and tight rhythm section. In another example, side chaining may be used in other applications, such as where a music track can be automatically ducked (e.g. reduced in volume) whenever the voiceover is present to ensure that the voiceover remains clear and audible over the music.

In one or more exemplary embodiments, the personal mixing operations may additionally or alternatively include one or more advanced processing algorithms, such as one or more audio processing that uses ML to adjust mixing parameters and/or control the mixing operations. The advanced processing techniques may include spatialization, denoising, auto mixing, and/or one or more other advanced audio processing operations. Spatialization may create a sense of space and depth within an audio mix by, for example, placing different sounds in different locations within the stereo or surround sound field, creating a more immersive and realistic listening experience. Spatialization techniques may include panning, reverberation, and delay effects, as well as more advanced techniques like binaural and ambisonic processing. Denoising may include removing unwanted noise from an audio signal (e.g. drum bleed). Noise can come from a variety of sources, including background hum, hiss, and/or electronic interference. Denoising techniques may include spectral subtraction, noise gating, and/or adaptive filtering, as well as more advanced techniques like ML-based noise reduction algorithms. Denoising techniques may remove and/or attenuate unwanted noise while preserving the quality and clarity of the desired audio signal. Auto mixing may include one or more mixing operations that are at least partially automated (e.g. using ML). Auto mixing may include performing one or more audio processing operations to, for example, emphasize or deemphasize one or more channels.

The I/O interface 208 may be configured to receive one or more inputs that allow the PSM transmitter 102 to receive audio signals from different sources, such as microphones, instruments, and playback devices. The audio signals may be received on one or more channels. The I/O interface 208 may include one or more input connections configured to receive input data and/or signals using one or more wired and/or wireless communication protocols, and/or may include one or more input devices (e.g. keyboard, control panel, graphical user interface (GUI), human-machine interface, or the like). Additionally, or alternatively, the I/O interface 208 may include one or more output connections configured to transmit output data and/or signals using one or more wired and/or wireless communication protocols, and/or may include one or more output devices (e.g. speaker, display, GUI, etc.). The I/O interface 208 may include a dedicated audio interface (e.g., 3.5 mm connector), a general-purpose interface (e.g., a universal serial bus (USB) connector), an XLR connector, or any other type of interface.

Inputs to the PSM transmitter 102 (e.g. via the I/O interface 208 and/or transceiver 206) may be any data and/or information, audio signals, electrical signals, and/or electromagnetic signals. The inputs may originate from any input devices and/or sources (e.g., from the performer(s), instrument(s), mixer(s), amplifier(s), audio track(s), etc.). The inputs may be processed and/or transmitted by the PSM transmitter 102. Outputs from the PSM transmitter 102 (e.g. via the I/O interface 208 and/or transceiver 206) may be any data and/or information processed by the PSM transmitter 102, audio signals (e.g., mixed and/or processed audio), electrical signals, and/or electromagnetic signals that may be played back via output devices, stored, and/or processed by other devices. Output devices that may be connected to the PSM transmitter 102 may include the PSM receiver(s) 104 (e.g., wearable packs (e.g., belt packs) associated with headsets, a wireless headset), electronic device(s), speakers, a user computing device, an electronically-readable memory, a transceiver associated with a musical instrument, an output interface (e.g., an XLR connector, USB connector, 3.5 mm connector, etc.), a server associated with a computing network (e.g., local network, public network such as the Internet), a computing device (e.g., smartphone, tablet) with integrated speakers or connected headphones, etc.

With continued reference to FIG. 2, in an exemplary embodiment, the PSM receiver 104 may include processing circuitry 212, memory 214, transceiver(s) 216, and/or I/O interface(s) 218. One or more data buses may interconnect the processing circuitry 212, the memory 214, transceiver(s) 216, and/or I/O interface(s) 218. The PSM receiver 104 may be implemented using one or more ICs, software, or a combination thereof, configured to operate as described herein. Like processing circuitry 202, the processing circuitry 212 may include circuit(s) or processor(s), or a combination thereof. The memory 214 may comprise any memory, such as RAM, ROM, flash memory, or any other electronically readable memory, or the like. The memory 214 may include one or more memory units.

In an exemplary embodiment, the PSM receiver 104 may receive one or more data units from the PSM transmitter 102 using the transceiver 216. Processing circuitry 212 may decode the data unit(s) received by the PSM receiver 104 to generate one or more audio signals. The transceiver 216 may be configured to receive/send signals from/to the PSM transmitter 102 using one or more communication protocols, such as those usable by the PSM transmitter 102 and discussed above. For example, the transceiver 216 may be configured to transmit and/or receive signals using an IEEE 802.11 WIFI protocol, an IEEE 802.15.1 protocol (e.g., Bluetooth), an IEEE 802.15.4 protocol (e.g., Zigbee), or one or more other wireless personal area network (WPAN) protocols, a 3GPP cellular protocol, a LAN protocol, HTTP), FM radio, infrared, one or more optical protocols, fiber optics, ISM bands defined by the International Telecommunication Union (ITU) Radio Regulations (e.g., a 2.4 GHz-2.5 GHz band, a 5.75 GHz-5.875 GHz band, a 24 GHz-24.25 GHz band, and/or a 61 GHz-61.5 GHz band, etc.), VHF band(s) (e.g., 30 MHz-300 MHz band) and/or via (e.g., one or more channels within) UHF band(s) (e.g., 300 MHz-3 GHz). The communication protocols that may be used are not limited to these example protocols.

The processing circuitry 212 may be configured to perform one or more operations of the PSM receiver 104, including controlling the operation of the PSM receiver 104 and/or operation of one or more of its other components. For example, the processing circuitry 212 may process data and/or information associated with the operation of the PSM receiver 104 and/or received by the PSM receiver 104 (e.g., from the PSM transmitter 102 and/or other device(s) via I/O interface 218, such as output device 250), and/or control the transceiver 216 to perform transmission and/or reception operations. The processing circuitry 212 may decode the data unit(s) received by the PSM receiver 104 to generate one or more audio signals. The processing circuitry 212 may be configured to execute machine readable instructions stored in memory 214 to perform one or more operations of the PSM receiver 104.

Similar to processing circuitry 202, the processing circuitry 212 may be configured to perform one or more audio mixing operations, digital signal processing (DSP), and/or other signal processing on the audio signals received (e.g. via transceiver 216) to generate processed audio data. Such signal processing operations (which may include mixing operations) may be in addition to, or alternatively to, processing performed by the PSM transmitter 102.

The audio signals generated by the PSM receiver 104 may be provided to the performer associated with the PSM receiver 104 to provide the performer with monitoring feedback. This feedback allows performers to hear themselves, instruments, audio tracks, and/or other performers more clearly. The I/O interface 218 may be configured similarly as the I/O interface 208, and include one or more input connections configured to receive input data and/or signals using one or more wired and/or wireless communication protocols, and/or may include one or more input devices (e.g. keyboard, control panel, graphical user interface (GUI), human-machine interface, or the like). Additionally, or alternatively, the I/O interface 218 may include one or more output connections configured to transmit output data and/or signals using one or more wired and/or wireless communication protocols, and/or may include one or more output devices (e.g. speaker, display, GUI, etc.). The I/O interface 218 may include a dedicated audio interface (e.g., 3.5 mm connector), a general-purpose interface (e.g., a universal serial bus (USB) connector), an XLR connector, or any other type of interface. Outputs from the PSM receiver 104 may be any data, information; and/or audio signals, electrical signals, and/or electromagnetic signals that may be played back via output devices, stored, and/or processed by other devices.

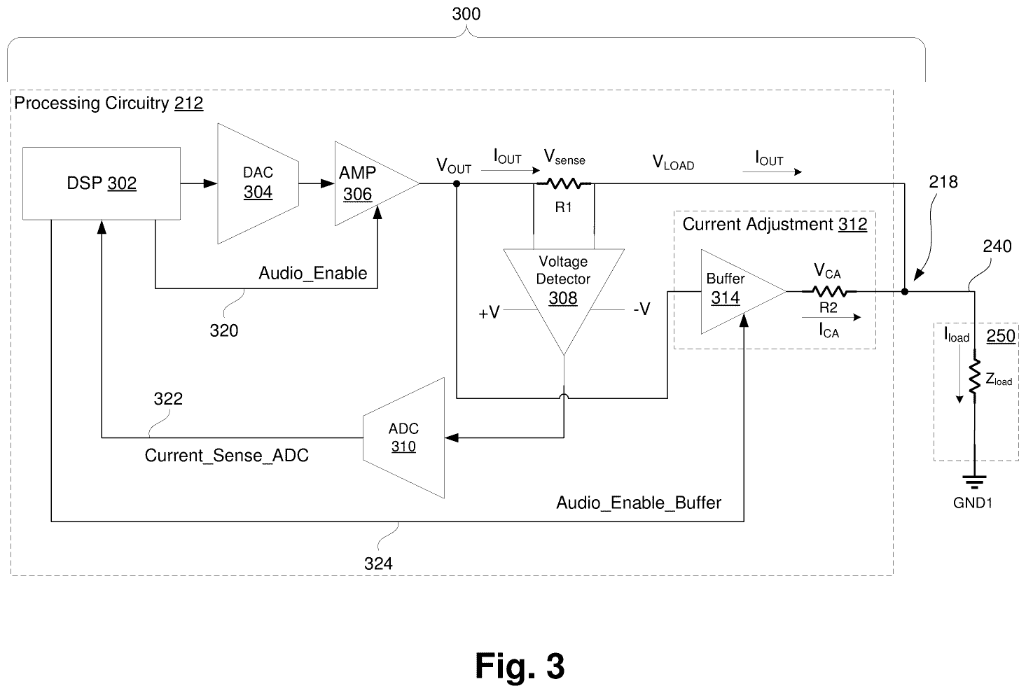

The PSM receiver 104 may be connected to one or more devices 250 by connection 240 via the I/O interface 218. The connection 240 may be a wired connection that electrically and/or communicatively couples the device(s) 250 with the PSM receiver 104. The device(s) 250 may be an output device, such as an IEM worn by a user associated with the PSM receiver 104. In this example, the PSM receiver 104 may be a bodypack that is worn by the user, where the IEM 250 is plugged into the PSM receiver 104 via the I/O interface 218. The IEM 250 may have a load impedance Z_{LOAD} (FIG. 3).

The PSM receiver 104 (e.g., processing circuitry 212) may be configured to detect the impedance (e.g., Z_{LOAD}) of the connected device(s) 250, such as an IEM. The PSM receiver 104 may be configured to adjust the current (and/or voltage) delivered to (driving) the connected IEM 250. The adjustment of the current (and/or voltage) may be based on the detected impedance. For example, if the detected impedance is less than an impedance threshold Z_{TH}, the PSM receiver 104 may increase the current delivered to the connected IEM 250. If the detected impedance is greater than an impedance threshold Z_{TH}, the PSM receiver 104 may decrease the current delivered to the connected IEM 250. In one or more embodiments, the PSM receiver 104 is configured to determine the impedance of the connected device(s) 250 and adaptively adjust the current provided to the connected device(s) 250 in real time.

By adaptively adjusting the current based on the load impedance of the connected IEM 250, the efficiency of the PSM receiver 104 is improved by reducing power losses for high-impedance loads while improving audio quality (e.g., reducing audible distortion), ensuring sufficient current is available to drive the IEM 250 effectively, maintain signal integrity and characteristics (e.g., by reducing voltage drops and distortion), and protecting the PSM receiver 104 from overloading. In one or more embodiments, the processing circuitry 212 may be configured to detect or otherwise determine the load impedance, determine the validity of the determined load impedance, and/or control the PSM receiver 104 to adjust the current delivered to the connected IEM 250. Additionally, or alternatively, the PSM receiver 104 (e.g., processing circuitry 212) may adjust one or more voltages provided by PSM receiver 104 to the IEM 250 and/or provided by the processing circuitry 212 and/or one or more components thereof.

In one or more embodiments, the PSM receiver 104 (e.g., processing circuitry 212) may be configured to measure (or otherwise determine) the voltage and/or current provided to connected device(s) 250 by the PSM receiver 104, and determine the impedance of the connected device(s) 250 based on the determined voltage and/or current.

Other devices in the audio system (e.g., mixers, amplifiers, speakers, IEMs, musical instruments, general-purpose computing devices, etc.), including device(s) 250, may have an architecture similar to the PSM transmitter 102 and/or PSM receiver 104. For example, one or more of the other devices (e.g., IEM 250) in the audio system may comprise corresponding memories, processing circuitries transceivers, and/or I/O interfaces.

FIG. 3 illustrates an audio device 300 according to one or more exemplary embodiments. In this example, the audio device 300 may be a PSM receiver and may be an embodiment of the PSM receiver 104. Although this example is described with respect to the audio device 300 being a PSM receiver, the aspects are applicable to other audio devices as well as other non-audio devices.

The PSM receiver 300 may be removably connected to one or more devices 250 by connection 240 via the I/O interface 218. The connection 240 may be a wired connection that electrically and/or communicatively couples the device(s) 250 with the PSM receiver 104. In other embodiments, the connection 240 may be wireless, wired, or include both wired and wireless connections. The device(s) 250 may be an output device, such as an IEM worn by a user associated with the PSM receiver 104. In this example, the PSM receiver 104 may be a bodypack that is worn by the user, where the IEM 250 is plugged into the PSM receiver 104 via the I/O interface 218. The IEM 250 may have a load impedance Z_{LOAD}. Like PSM receiver 104 illustrated in FIG. 2, the PSM receiver 300 may include processing circuitry 212.

The processing circuitry 212 may be configured to determine the impedance (e.g., Z_{LOAD}) of the connected device(s) 250, such as IEM 250. The processing circuitry 212 may determine the validity of the determined impedance. For example, the processing circuitry 212 may compare the determined impedance to one or more threshold values to determine the validity of the determined impedance. This may include validating one or more components defining the impedance, including the voltage at the load and/or the current delivered to the load.

The processing circuitry 212 may be configured to adjust the current (I_{LOAD}) delivered to the connected IEM 250. In this example, the processing circuitry 212 may be configured to adjust the current (I_{LOAD}) delivered to the connected IEM 250 based on the determined impedance (e.g., Z_{LOAD}). As discussed in more detail below, the current (I_{LOAD}) delivered to the connected IEM 250 may be the sum of multiple currents, including I_{OUT} and I_{CA}. For example, the total current may satisfy the following equation:

$${I}_{LOAD} = {I}_{OUT} + {I}_{CA}$$

In an exemplary embodiment, the processing circuitry 212 may include digital signal processor (DSP) 302, digital-to-analog converter (DAC) 304, first amplifier 306, voltage detector 308, analog-to-digital convertor (ADC) 310, and a current adjuster 312.

The output of the DSP 302 may be connected to the input of the DAC 304, where the output of the DAC 304 is connected to the first amplifier 306. The DAC 304 may be configured to convert a digital signal (e.g., digital audio signal) generated by the DSP 302 to an analog signal, where the analog signal is then provided as an input to the first amplifier 306.

The output of the first amplifier 306 may be connected in series with a resistor R1 (also referred to as sense resistor R1) and the connected device(s) 250. The voltage detector 308 may be configured to detect the voltage drop Vₛₑₙₛₑ across the resistor R1. The voltage detector 308 may be an operational amplifier configured to detect the voltage drop Vₛₑₙₛₑ across the resistor R1. The output of voltage detector 308 (e.g., the output of the operational amplifier) may be connected to the input of the ADC 310, whose output is connected to an input of the DSP 302. The ADC 310 may be configured to convert an analog signal generated by the voltage detector 308 and corresponding to the voltage (e.g., Vₛₑₙₛₑ) detected by the voltage detector 308 to a digital signal 322 (“Current_Sense_ADC”) corresponding to the detected voltage (Vₛₑₙₛₑ). The DSP 302 may be configured to determine the output current (I_{OUT}) of the first amplifier 306 based on the value of detected voltage (Vₛₑₙₛₑ) and the known resistance value of the resistor R1 by applying Ohm's law. For example, the output current (I_{OUT}) may satisfy the following equation:

$${I}_{OUT} = \frac{{V}_{sense}}{R 1}$$

Because the resistor R1 is connected in series with the load (Z_{LOAD} of device 250), the current through the sense resistor R1 (I_{OUT}) is approximately equal the current (e.g., I_{LOAD}) being delivered to the load. That is, with the current adjuster 312 disabled, I_{OUT}≈I_{LOAD}. Further, because the value of the resistor R1 is low (e.g., 0.5 ohms), the voltage output of the first amplifier (e.g., V_{OUT}) is approximately equal to the voltage at the load (e.g., V_{LOAD}). If the voltage drop across resistor R1 is considered, V_{LOAD}=V_{OUT}−Vₛₑₙₛₑ, where Vₛₑₙₛₑ is the voltage drop across the resistor R1.

The current adjuster 312 may include a second amplifier 314 and a resistor R2 connected in series at its output to the connected device(s) 250. The node between the resistor R2 and the connected device(s) 250 may represent the I/O interface 218. The second amplifier 314 may be a buffer (e.g., a unity gain buffer). The resistor R2 may be the same resistance value as resistor R1. In one or more other embodiments, the resistors R1 and R2 may have different resistance values. Additionally, or alternatively, the resistor R1 and/or resistor R2 may have a variable resistance that may be controlled by the DSP 302. The buffer 314 may be a unity gain buffer configured to transfer voltage (V_{OUT}) from its input to its output without amplification or attenuation (gain of 1). In another embodiment, the second amplifier 314 may have an adjustable gain, where the DSP 302 may be configured to adjust the gain.

The buffer 314 may have a high input impedance so that the current I_{OUT} provided by the first amplifier 306 will flow to the load in parallel to the current adjuster 312. In this example, the output voltage of the buffer 314 will be V_{OUT}, and the current I_{CA} that may be provided by the buffer 314 will be:

$${I}_{CA} = \frac{{V}_{CA}}{R 2}$$

Where V_{CA} is the voltage drop across resistor R2.

When R2 has the same resistance value as R1, the output current I_{CA} of the buffer 314 will be the same as the output current I_{OUT} of the first amplifier 306. With this relationship, when the current adjuster 312 is enabled, the output current I_{OUT} of the first amplifier 306 will be half as compared to when the current adjuster 312 is disabled because, when enabled, the current deliverable by the audio device 300 is divided (e.g., equally divided) between the output path of the amplifier 306 and the output path of the current adjuster 312. This relationship also provides that the total current deliverable/available at the load I_{LOAD} may be double as compared to when the current adjuster 312 is disabled. For example, the total current that may be deliverable to the load will be:

$${I}_{LOAD \_ ENABLED} = {I}_{OUT} + {I}_{CA} = 2 \times {I}_{OUT}$$

where I_{LOAD_ENABLED} is the current that may be provided to the load when the current adjuster 312 is enabled.

Conversely, when the current adjuster 312 is disabled, the current that may be provided to the load I_{LOAD} will be I_{OUT}:

$${I}_{LOAD \_ DISABLED} = {I}_{OUT}$$

where I_{LOAD_DISABLED} is the current that may be provided to the load when the current adjuster 312 is disabled.

The DSP 302 may be configured to determine the impedance (e.g., Z_{LOAD}) of the connected device(s) 250, and control the operation of the current adjuster 312 based on the determined impedance Z_{LOAD}. For example, the DSP 302 may determine the impedance Z_{LOAD} of the connected device(s) 250 based on the current I_{LOAD} delivered to the load and the voltage V_{LOAD} at the load, where I_{LOAD} is based on the operational status of the current adjuster 312. When the current adjuster 312 is disabled, in an exemplary embodiment, the DSP 302 may determine the impedance based on the following equation:

$${Z}_{LOAD} = \frac{{V}_{OUT} - {V}_{sense}}{{I}_{OUT}} = \frac{{V}_{LOAD}}{{I}_{OUT}} = \frac{{V}_{LOAD}}{{I}_{LOAD}} \approx \frac{{V}_{OUT}}{{I}_{OUT}}$$

Where V_{OUT} is the voltage output of the amplifier 306, Vₛₑₙₛₑ is the voltage drop across R1, I_{OUT} is the current provided by the amplifier 306, V_{LOAD} is the voltage at the load (e.g., voltage output of the amplifier 306 when considering the voltage drop across R1), and I_{LOAD} is the current delivered to the load. Here, I_{LOAD} DISABLED equals I_{OUT} because I_{CA} is zero.

In an exemplary embodiment, the DSP 302 may determine the impedance Z_{LOAD} of the connected device(s) 250 further based on a compensation factor associated with the operational status of the current adjuster 312. For example, when the current adjuster 312 is enabled, the DSP 302 may adjust the sensed current through resistor R1 based on a compensation factor (C). The compensation factor C may have a value that is associated with the resistance values of resistors R1 and R2. For example, when the resistors R1 and R2 have the same resistance value, the compensation factor may have a value of, for example, 2. The compensation factor may compensate for the reduction in the output current I_{OUT} of the first amplifier 306 when the current adjuster 312 is enabled, as described above.

The compensation factor may be set to account for the additional current deliverable or available to the load by the enabled current adjuster 312 when determining the impedance Z_{LOAD} of the connected device(s) 250. When the current adjuster 312 is enabled, in an exemplary embodiment, the DSP 302 may determine the impedance based on the following equation:

$${Z}_{LOAD} = \frac{{V}_{OUT} - {V}_{sense}}{{I}_{OUT} \times C} = \frac{{V}_{LOAD}}{{I}_{OUT} + {I}_{CA}} = \frac{{V}_{LOAD}}{{I}_{LOAD \_ ENABLED}} \approx \frac{{V}_{OUT}}{{I}_{OUT} \times C}$$

Where V_{OUT} is the voltage output of the amplifier 306, Vₛₑₙₛₑ is the voltage drop across R1, I_{OUT} is the current provided by the amplifier 306, C is the compensation factor, V_{LOAD} is the voltage at the load (e.g., voltage output of the amplifier 306 when considering the voltage drop across R1), and I_{LOAD} is the current deliverable or available to the load. In this example, the current I_{OUT} will correspond to half of the current deliverable or available to the load and the compensation factor can have a value of two to compensate for I_{LOAD_ENABLED}=I_{OUT}+I_{CA}=2×I_{OUT}.

In summary, when considering the operational mode (enabled/disabled) of the current adjuster 312, the impedance of the load Z_{LOAD} may satisfy the following:

$${Z}_{LOAD} = \{ \begin{matrix}\frac{{V}_{OUT} - {V}_{sense}}{{I}_{OUT}} = \frac{{V}_{LOAD}}{{I}_{LOAD}} \approx \frac{{V}_{OUT}}{{I}_{OUT}} , & CA disabled \\ \frac{{V}_{OUT} - {V}_{sense}}{{I}_{OUT} \times C} = \frac{{V}_{LOAD}}{{I}_{OUT} + {I}_{CA}} \approx \frac{{V}_{OUT}}{{I}_{OUT} \times C} , & CA enabled\end{matrix}$$

To control the current adjuster 312, the DSP 302 may compare the determined impedance Z_{LOAD} to an impedance threshold value Z_{TH}. Based on the comparison, the current adjuster 312 may selectively enable the current adjuster 312 to selectively increase the current available/deliverable to the load by enabling the output current I_{CA}. The DSP 302 may be configured to selectively enable the current adjuster 312 via enable signal 324 (e.g. Audio_Enable_Buffer signal).

The DSP 302 may dynamically enable and disable the availability of the current I_{CA} to adjust the total current I_{LOAD} deliverable to the load, device 250. For example, if the detected impedance is less than an impedance threshold Z_{TH}, the DSP 302 may increase the available current I_{LOAD} deliverable to the connected IEM 250 by enabling the current adjuster 312, which may provide current I_{CA} to the load (and/or increasing the available current I_{CA} that may be deliverable by the current adjuster 312 by adjusting the gain of the amplifier 314). If the detected impedance is greater than an impedance threshold Z_{TH}, the DSP 302 may decrease the current that may be delivered to the connected device 250 by disabling the current adjuster 312, thereby reducing the available current that may be provided to the load (and/or decreasing the available current I_{CA} that may be deliverable by the current adjuster 312). In one or more exemplary embodiments, the DSP 302 may be configured to determine the impedance of the connected device(s) 250 and adaptively adjust the current that may be provided to the connected device(s) 250 in real time.

In an exemplary embodiment, the current adjuster 312 may include one or more additional amplifiers 314.2, 314.3, . . . 314.N in addition to amplifier 314.1 (configured to deliver current I_{CA}), where the additional amplifiers 314.2, 314.3, . . . 314.N may be configured to respectively deliver currents I_{CA-2}, I_{CA-3}, . . . . I_{CA-N} to the electronic device(s) 250. The currents I_{CA-2}, I_{CA-3}, . . . . I_{CA-N} may be different from current I_{CA}. The additional amplifiers 314.2, 314.3, . . . 314.N may have a corresponding resistor R2.2, R2.3, . . . . R2.N connected in series with their respective output. The resistors R2.2, R2.3, . . . . R2.N may have different resistance values from each other and/or from R2. The additional amplifiers 314.2, 314.3 . . . 314.N and corresponding resistors R2.2, R2.3, . . . . R2.N may be connected in parallel with amplifier 314.1 and resistor R2.1. In an exemplary embodiment, the DSP 302 may be configured to selectively enable one or more of the amplifiers 314.1, 314.2, 314.3, . . . 314.N to provide different additional currents I_{CA}, I_{CA-2}, I_{CA-3}, . . . . I_{CA-N} to the connected device(s) 250. The selective enabling of the amplifier(s) may be based on the determined impedance. For example, different impedance threshold values may be associated with the additional amplifiers 314.2, 314.3 . . . 314.N to provide the current adjuster 312 with additional granularity in adjusting the available current deliverable to the connected device(s) 250.

In one or more exemplary embodiments, the amplifier 306 and/or amplifier 314 may have fixed gains, and the DSP 302 may have knowledge of such fixed gains. In one or more other embodiments, the amplifier 306 and/or amplifier 314 may have variable gains and the DSP 302 may be configured to control the gain of the amplifier 306 and/or amplifier 314. For fixed gain configurations, the Audio_Enable signal 320 and Audio_Enable_Buffer signal 324 may be used to enable and disable the respective amplifiers 306 and 314. In variable gain configurations, the Audio_Enable signal 320 and Audio_Enable_Buffer signal 324 may be used to control the respective gains of the amplifiers 306 and 314.

In an exemplary embodiment, the amplifier 314 may have a variable gain and/or the resistor R2 may have a variable resistance, and the DSP 302 may be configured to control the gain of the amplifier 314 and/or the resistance of the resistor R2. The variable gain and/or variable resistance may be adjusted by the DSP 302 to vary the available current I_{CA} deliverable/available to the connected device(s) 250.

In an exemplary embodiment, the DSP 302 may map digital outputs provided to the DAC 304 to corresponding voltages which drive the amplifier 306. Similarly, the DSP 302 may map digital input signals received from the ADC 310 to corresponding voltage values output from the voltage detector 308. In these examples, the mapping(s) may have a linear relationship, but is not limited thereto. The mapping(s) may be performed, for example, during the calibration of the device 300.

By adaptively adjusting the available current based on the load impedance of the connected device(s) 250, the DSP 302 improves the efficiency of the processing circuitry 212 by reducing power losses for low-impedance loads while improving audio quality (e.g., reducing audible distortion), ensuring sufficient current is available to drive the connected device(s) 250 effectively, maintain signal integrity and characteristics (e.g., by reducing voltage drops and distortion), and protecting the processing circuitry 212 from overloading.

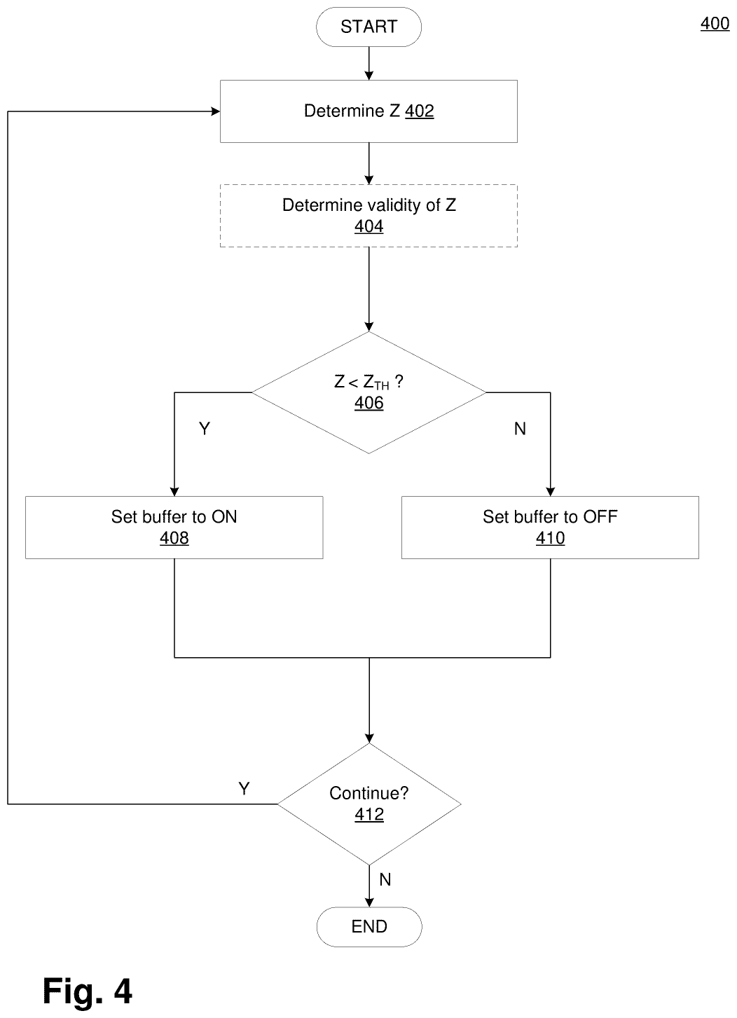

FIG. 4 shows an example method 400 of impedance detection and current adjustment according to one or more exemplary embodiments. Two or more of the various operations of the method 400 may be performed simultaneously in one or more embodiments. Further, the order of the various operations is not limiting and the operations may be performed in a different order in one or more embodiments.

At operation 402, processing circuitry 212 (e.g. DSP 302) may determine (e.g., estimate) the impedance (e.g., Z_{LOAD}) of the connected device(s) 250, such as an IEM. For example, the processing circuitry 212 may determine the impedance Z_{LOAD} of the connected device(s) 250 based on the current I_{LOAD} delivered to the load and the voltage V_{LOAD} at the load. For example, the processing circuitry 212 may determine the Z_{LOAD} based on the following equation:

$${Z}_{LOAD} = \frac{{V}_{LOAD}}{{I}_{LOAD}}$$

At operation 404, processing circuitry 212 (e.g. DSP 302) may determine the validity of the determined impedance Z_{LOAD} of the connected device(s) 250. For example, the processing circuitry 212 may compare the determined impedance Z_{LOAD} to one or more threshold values (e.g., voltage threshold value(s), current threshold value(s), and/or impedance threshold value(s)) and/or other information). The comparison(s) may then be used to determine if the determined (e.g., estimated) impedance of Z_{LOAD} is valid. Validating the impedance Z_{LOAD} may include validating one or more components defining the impedance, including the voltage at the load and/or the current delivered to the load.

At operation 406, processing circuitry 212 (e.g. DSP 302) may adjust the current delivered to (driving) the connected device(s) 250 based on the determined impedance Z_{LOAD} of the connected device(s) 250. For example, the processing circuitry 212 may compare the determined impedance Z_{LOAD} to an impedance threshold value Z_{TH} (e.g., 10 ohms).

If the determined impedance Z_{LOAD} is less than the impedance threshold value Z_{TH} (YES at operation 406), the method 400 proceeds to operation 408 where the processing circuitry 212 may increase the available current that may be delivered to the connected device(s) 250. For example, the processing circuitry 212 may enable the current adjuster 312 (e.g., enable buffer 314) to increase the available current that may be deliverable to the connected device(s) 250 by making current I_{CA} available to the load.

If the determined impedance Z_{LOAD} is greater than the impedance threshold value Z_{TH} (NO at operation 406), the method 400 proceeds to operation 410 where the processing circuitry 212 may decrease the available current that may be delivered to the connected device(s) 250 by disabling the current adjuster 312. For example, the processing circuitry 212 may disable the current adjuster 312 (e.g., disable the buffer 314) to reduce the available current that may be deliverable to the connected device(s) 250.

At operation 412, the processing circuitry 212 (e.g. DSP 302) may determine if the method 400 should be repeated (e.g., for a next sample). If so, the method 400 may return to operation 402. Otherwise, the method 400 may end.

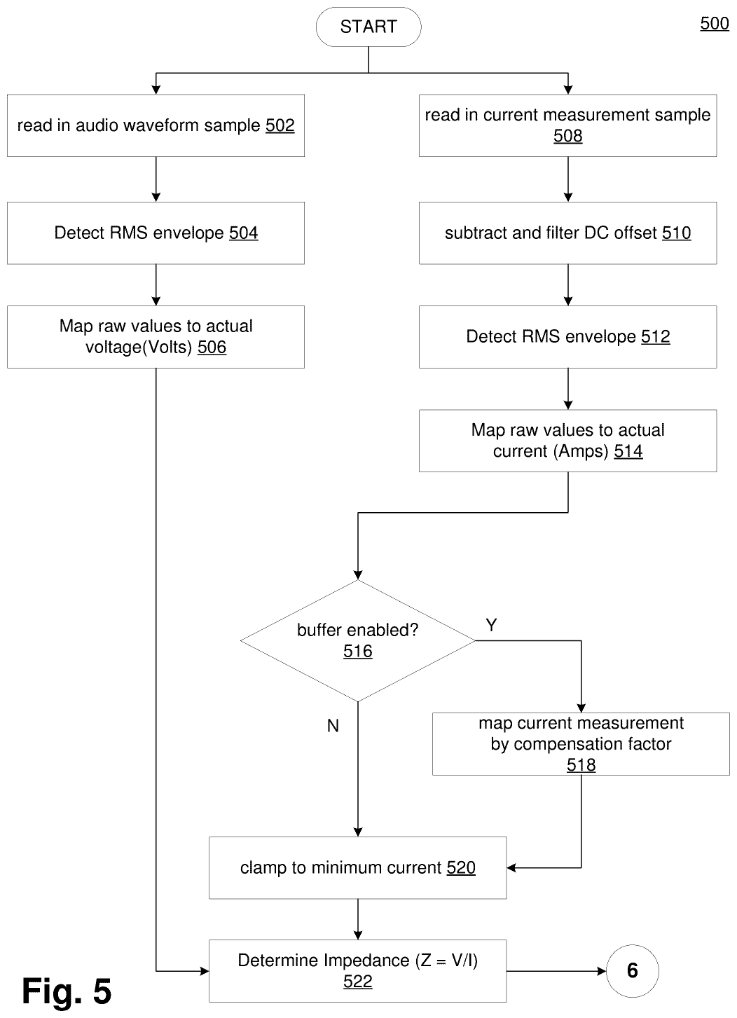

FIGS. 5-7 collectively show impedance detection and current adjustment methods. The individual methods 500, 600, and 700 may collectively be embodiments of the method 400. Two or more of the various operations of the methods 500, 600, 700 may be performed simultaneously in one or more embodiments. Further, the order of the various operations is not limiting and the operations may be performed in a different order in one or more embodiments.

With reference to FIG. 5, at operation 502, processing circuitry 212 (e.g. DSP 302) may generate an audio waveform sample and/or the DSP 302 may receive an audio waveform sample as an input.

At operation 504, the audio waveform sample may be provided to an envelope detector of the DSP 302 (e.g., Root Mean Square (RMS) envelope detector) to measure the effective voltage values of the audio waveform sample (e.g., measure the envelope of the modulated waveform), such as the voltage values of V_{OUT} (or V_{LOAD} when considering the voltage drop of R1, Vₛₑₙₛₑ). The RMS envelope detector may square the audio waveform sample (e.g., using an analog multiplier or a squaring circuit) to provide that all voltage values are positive and emphasize larger amplitudes more than smaller ones, average the squared values (e.g., using a low-pass filter to calculate the mean (average) of the squared values, as well as smooths out rapid fluctuations, where the filter may be a resistor-capacitor (RC) network), and perform a square root of the averaged values to convert the average power into a value proportional to the original signal's amplitude. Other envelope detection and/or moving-average filtering techniques may be used in other embodiment(s). Additionally, or alternatively, the envelope detection and/or moving-average filtering may be performed by one or more analog circuits and/or digital algorithms.

At operation 506, the envelope signal is converted to voltage by mapping the values from the envelope detector to voltage values generated by the amplifier 306 that drives the load. For example, the DSP 302 may map the various values of the audio waveform sample to the resulting voltages generated by the amplifier 306. The mapping may be linear, but is not limited thereto. The mapped voltages may then be used by the DSP 302 to determine the impedance in operation 522 as discussed below.

At operation 508, the processing circuitry 212 (e.g. DSP 302) may receive and process the digital signal (Current_Sense_ADC) from ADC 310 corresponding to the sensed current delivered by the amplifier 306 (e.g., using the detected voltage drop Vₛₑₙₛₑ across R1 and the known value of R1).

At operation 510, the DC components of the signal from the ADC 310 may be filtered out. The processing circuitry 212 (e.g. DSP 302) may filter out the DC components of the signal from the ADC 310.

At operation 512, the filtered signal may be subjected to envelope detection, such as RMS envelope detection. For example, the filtered signal from the ADC 310 may be provided to an envelope detector of the DSP 302 (e.g., RMS envelope detector) configured to measure the effective value of the voltage signal (corresponding to the sensed current). The RMS envelope detector may square the signal, average the resulting squared values, and perform a square root of the averaged values to convert the average power into a value proportional to the original signal's amplitude. Other envelope detection and/or moving-average filtering techniques may be used in other embodiment(s). Additionally, or alternatively, the envelope detection and/or moving-average filtering may be performed by one or more analog circuits and/or digital algorithms.

At operation 514, the envelope signal from ADC 310 is converted to current values by mapping the values from the envelope detector to current values generated by the amplifier 306 that are delivered to resistor R1 and the load. For example, the DSP 302 may map the various values to the resulting currents generated by the amplifier 306. The mapping may be linear, but is not limited thereto. The mapped current values may then be used by the DSP 302 to determine the impedance in operation 522 as discussed below.

At operation 516, it may be determined if the current adjuster 312 (e.g., buffer 314) is enabled. In an exemplary embodiment, the DSP 302 may determine if the current adjuster 312 is enabled by determining the present status of the Audio_Enable_Buffer signal 324 controlling the current adjuster 312.

If the current adjuster 312 is enabled, the method 500 transitions to operation 518, where the current mapping may be adjusted based on a compensation factor C. When the current adjuster 312 is enabled, the current I_{LOAD} includes the current I_{OUT} from amplifier 306 and the current I_{CA} from the current adjuster 312. Therefore, the current being sensed via the voltage detector 308 and R1 represents a fraction (e.g., half) of the actual current being delivered to the load. The compensation factor C may be used to adjust this fractional current value to represent the full current being delivered to the load. For example, the correction factor may be two, and the fractional current (e.g., I_{OUT}) may be multiplied by the correction factor to determine the current I_{LOAD}. The DSP 302 may adjust the sensed current through resistor R1 based on the compensation factor (C). The compensation factor C may have a value that is associated with the resistance values of resistors R1 and R2. For example, when the resistors R1 and R2 have the same resistance value, the compensation factor may have a value of, for example, two. The compensation factor may be set to account for the additional current delivered to the load by the enabled current adjuster 312 when determining the impedance Z_{LOAD} of the connected device(s) 250.

At operation 520, the determined current I_{LOAD} may be clamped to a minimum current (e.g., a small minimum current) to prevent a zero divisor (denominator) in the calculation of the impedance in operation 522. That is, the clamping can be used to prevent a zero-valued current (I) in the calculation:

$$Z = \frac{V}{I} .$$

At operation 522, the impedance (e.g., Z_{LOAD}) of the connected device(s) 250 may be determined using the voltage (e.g., V_{LOAD} or V_{OUT}) delivered by the amplifier 306 and the I_{LOAD}. For example, the DSP 302 may determine the impedance Z_{LOAD} of the connected device(s) 250 based on the current I_{LOAD} delivered to the load and the voltage V_{LOAD} at the load. For example, the DSP 302 may determine the Z_{LOAD} based on the following equation:

$${Z}_{LOAD} = \frac{{V}_{LOAD}}{{I}_{LOAD}} .$$

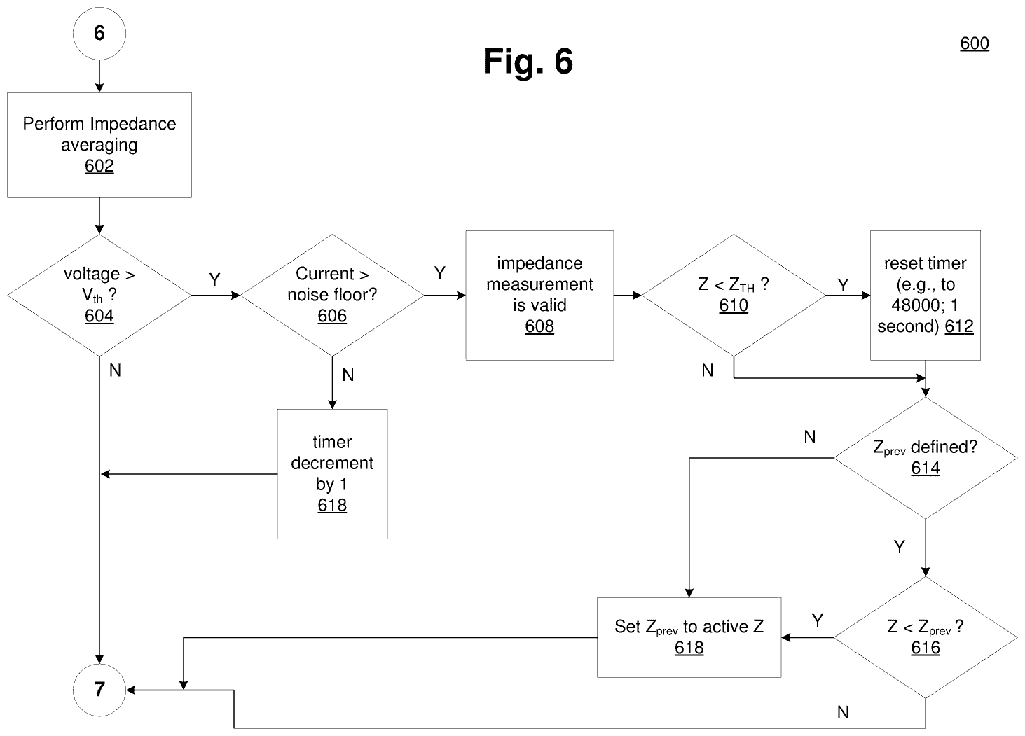

After operation 522, the flowchart transitions to method 600 illustrated in FIG. 6.

Turning to FIG. 6 and to method 600, which is a continuation of method 500, at operation 602, the determined impedance Z_{LOAD} is averaged. For example, an average impedance value is determined based on the determined impedance Z_{LOAD} and one or more previously determined impedance values (e.g., from previous sample(s)). The average may be a rolling or moving average, for example. The averaging may smooth out the impedance measurement/determination.

The DSP 302 may be configured to determine the average impedance value based on the determined impedance Z_{LOAD} and one or more previously determined impedance values. The DSP 302 may adjust the window size of the rolling/moving average. The DSP 302 may include an averager configured to determine the average. The averager may be a first order (e.g., single-pole) averager.

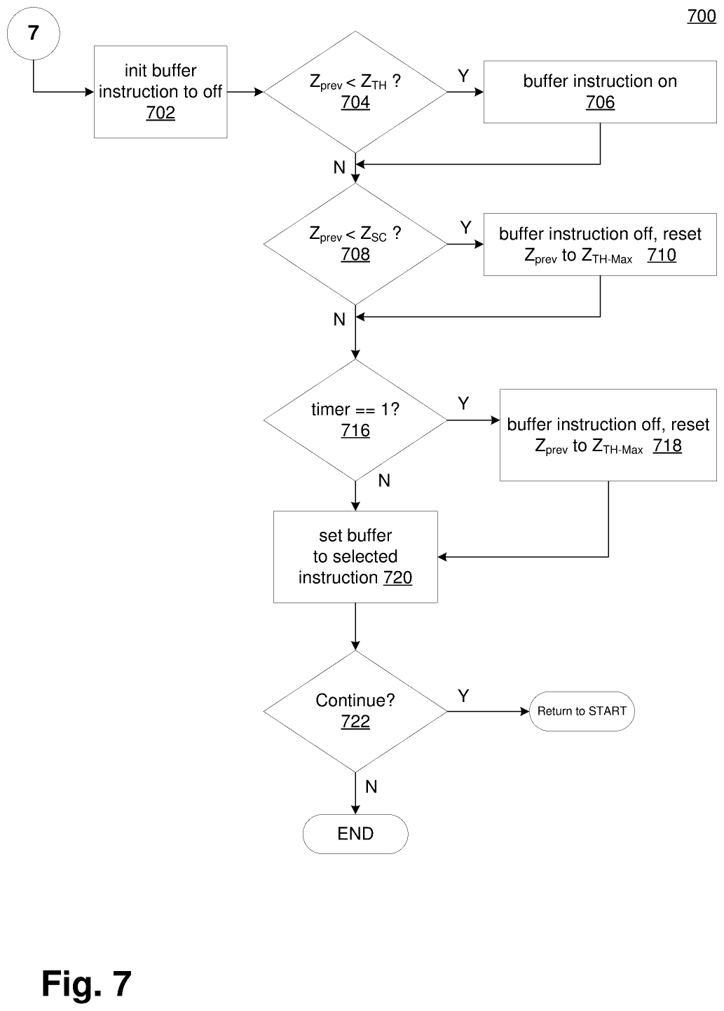

At operations 604 and 606, the averaged impedance may be validated. At operation 604, the determined voltage (e.g., V_{OUT} (or V_{LOAD}) when considering the voltage drop of R1, Vₛₑₙₛₑ)) is compared to a voltage threshold value (V_{TH}). The voltage threshold (V_{TH}) may be a minimum voltage threshold. The determined voltage (e.g., V_{OUT} or V_{LOAD}) may be compared to the voltage threshold (V_{TH}) to determine the validity of the average impedance (or the present impedance value Z_{LOAD}). The DSP 302 may be configured to compare the determined voltage (e.g., V_{OUT} or V_{LOAD}) to the voltage threshold (V_{TH}) to determine the validity of the average impedance (or the present impedance value Z_{LOAD}). If the determined voltage (e.g., V_{OUT} or V_{LOAD}) is greater than the voltage threshold (V_{TH}), the method 600 may transition to operation 606. If the determined voltage (e.g., V_{OUT} Or V_{LOAD}) is less than the voltage threshold (V_{TH}), the method 600 may transition to operation 702 (FIG. 7).

At operation 606, the determined current I_{LOAD} may be compared to a current threshold value (I_{TH}). The current threshold value (I_{TH}) may be a minimum current threshold, such as a current noise floor. The determined current I_{LOAD} may be compared to a current threshold value (I_{TH}) to determine the validity of the average impedance (or the impedance value Z_{LOAD}). The DSP 302 may be configured to compare the determined current I_{LOAD} to a current threshold value (I_{TH}) to determine the validity of the average impedance (or the present impedance value Z_{LOAD}). If the determined current I_{LOAD} is greater than the current threshold value (I_{TH}), the method 600 may transition to operation 608, where the average impedance (or the presently determined impedance value Z_{LOAD}) is determined to be a valid impedance measurement/determination. That is, when operations 604 and 606 are both determined in the affirmative, the average impedance (or the current impedance value Z_{LOAD}) may be determined to be a valid impedance measurement/determination. The DSP 302 may be configured to compare the determined voltage (e.g., V_{OUT} or V_{LOAD}) to the voltage threshold (V_{TH}) and/or compare the determined current I_{LOAD} to the current threshold value (I_{TH}).

If the determined current I_{LOAD} is less than the current threshold value (I_{TH}), the method 600 may transition to operation 618, where a timer is decremented (See operation 612). The timer may be decremented by 1 sample, where the timer initial value may be set to an initial timer value, such as 48000 samples (e.g., 1 second). After the timer is decremented, the method 600 transitions to operation 702 (FIG. 7).

At operation 610, the average impedance (“Z”) (or the impedance value Z_{LOAD}) may be compared to an impedance threshold Z_{TH}. The impedance threshold Z_{TH} may be, for example, 1-20 ohms, such as 6, 8, 10, 12, 14, 16, or 18 ohms, but is not limited thereto. This comparison may be used to determine whether to enable the current adjuster 312. For example, if the impedance is less than the threshold Z_{TH}, the current deliverable/available to the connected device(s) 250 may be increased (by enabling current adjuster 312). If the impedance is greater than (or equal to) the threshold Z_{TH}, the current deliverable/available to the connected device(s) 250 may be decreased (by disabling the current adjuster 312). In an exemplary embodiment, the DSP 302 may enable the current adjuster 312 (e.g., enable buffer 314) to make additional current I_{CA} deliverable/available to the connected device(s) 250, or disable the current adjuster 312 (e.g., disable buffer 314) to stop making the current I_{CA} deliverable/available to the connected device(s) 250 to reduce the overall available current deliverable to the load. The DSP 302 may compare the determined impedance Z_{LOAD} to an impedance threshold value Z_{TH} (e.g., 10 ohms).

If the determined impedance Z_{LOAD} is less than the impedance threshold value Z_{TH} (YES at operation 610), the method 600 proceeds to operation 612, where the timer is reset (e.g., to 48000 samples (e.g., 1 second), but is not limited thereto and other timer durations may be used). The DSP 302 may be configured to reset the timer. The method 600 then proceeds to operation 614.

If the determined impedance Z_{LOAD} is greater than the impedance threshold value Z_{TH} (NO at operation 610), the method 600 proceeds to operation 614, where it is checked if a previous (saved) impedance value (Zₚᵣₑᵥ) is defined. As discussed above, the methods may be repeatedly performed, and the previous (saved) impedance value (Zₚᵣₑᵥ) may correspond to the preceding average impedance (“Z”) (or the preceding determined impedance value Z_{LOAD}) of the preceding execution of the methods. The previous impedance value (Zₚᵣₑᵥ) may be used as a parameter for determining the operational state of the current adjuster 312 (buffer 314) as value as discussed in more detail below with reference to FIG. 7. In an exemplary embodiment, operation 614 may be omitted and the previous (saved) impedance value (Zₚᵣₑᵥ) may be initialized as an upper bound impedance threshold value Z_{TH-Max}. The upper bound impedance threshold value Z_{TH-Max} may be, for example, 64.0 ohms, but is not limited thereto.

At operation 614, if the previous (saved) impedance value (Zₚᵣₑᵥ) is undefined (NO at operation 614), such as when no previous impedance value exists (e.g., on the first execution of the methods), the method transitions to operation 618. At operation 618, the previous impedance value (Zₚᵣₑᵥ) may be updated/set to the value of the present average impedance Z (or the impedance value Z_{LOAD}). That is, the impedance value (Zₚᵣₑᵥ) may be initialized as the present average impedance Z (or the impedance value Z_{LOAD}). After operation 618, the method transitions to operation 702 (FIG. 7). Alternatively, if a previous (saved) impedance value (Zₚᵣₑᵥ) is not defined (NO at operation 614), the previous (saved) impedance value (Zₚᵣₑᵥ) may be set as the upper bound impedance threshold value Z_{TH-Max} instead of the present average impedance Z (or the impedance value Z_{LOAD}).

If the previous (saved) impedance value (Zₚᵣₑᵥ) is defined (YES at operation 614), the method transitions to operation 616, where the average impedance (“Z”) (or the impedance value Z_{LOAD}) may be compared to the previous impedance value (Zₚᵣₑᵥ). If the average impedance (“Z”) (or the impedance value Z_{LOAD}) is less than the previous impedance value (Zₚᵣₑᵥ), the method 600 transitions to operation 618, where the previous impedance value (Zₚᵣₑᵥ) is updated to the value of the present average impedance (“Z”) (or the impedance value Z_{LOAD}). Otherwise (NO at operation 616), the method 600 transitions to operation 702 of method 700 (FIG. 7).

Turning to FIG. 7 and to method 700, which is a continuation of methods 500 and 600, at operation 702, an initial enable/disable instruction for enabling/disabling the current adjuster 312 (buffer 314) may be set. For example, the enable/disable instruction may be set (initialized) to OFF (disabled). This value may be set by the DSP 302 and stored by the DSP 302 (e.g., in an internal memory of the DSP 302 (e.g., a register) and/or in a memory of the processing circuitry 212). As discussed below with respect to operation 720, the value of the enable/disable instruction may be provided to the current adjuster 312 (buffer 314) as the Audio_Enable_Buffer signal 324 to control the current adjuster 312 (buffer 314).

At operation 704, the previous impedance value Zₚᵣₑᵥ may be compared to the impedance threshold Z_{TH}. The impedance threshold Z_{TH} may be, for example, 10 ohms, but is not limited thereto. In the illustrated example, the impedance threshold Z_{TH} is the same value for both methods 600 and 700. In one or more embodiments, the impedance threshold Z_{TH} for method 600 may be a different value for method 700. The comparison of the previous impedance value Zₚᵣₑᵥ and the impedance threshold Z_{TH} may be used to determine whether to enable the current adjuster 312.

If the impedance value Zₚᵣₑᵥ is less than the threshold Z_{TH}, the method 700 transitions to operation 706, where the enable/disable instruction for enabling/disabling the current adjuster 312 (buffer 314) may be set to ON (enabled). The method 700 then transitions to operation 708.

If the impedance value Zₚᵣₑᵥ is greater than the threshold Z_{TH}, the method 700 transitions to operation 708, where the previous impedance value Zₚᵣₑᵥ may be compared to an impedance short-circuit threshold value Z_{SC}. The impedance short-circuit threshold value Z_{SC} may be, for example, 1 ohm, but is not limited thereto. The comparison of the impedance short-circuit threshold value Z_{SC} and the previous impedance value Zₚᵣₑᵥ may be used to determine whether there is a short-circuit, such as a short-circuit at the connected device(s) 250.

If the impedance value Zₚᵣₑᵥ is less than the impedance short-circuit threshold value Z_{SC}, the method 700 transitions to operation 710, where the enable/disable instruction for enabling/disabling the current adjuster 312 (buffer 314) may be set to OFF (disabled), and the impedance value Zₚᵣₑᵥ is reset to an upper bound impedance threshold value Z_{TH-Max}. The method 700 then transitions to operation 716. The upper bound impedance threshold value Z_{TH-Max} may be, for example, 64.0 ohms, but is not limited thereto. If the impedance value Zₚᵣₑᵥ is greater than the impedance short-circuit threshold value Z_{SC}, the method 700 transitions to operation 716.

At operation 716, it is determined if the timer has timed out (e.g., reached a value of 1). The timer may time out after being decremented (operation 618) during repeated executions of the methods 500, 600, and 700. If the timer has timed out (YES at operation 716), the method 700 transitions to operation 718, where the enable/disable instruction for enabling/disabling the current adjuster 312 (buffer 314) may be set to OFF (disabled), and the impedance value Zₚᵣₑᵥ is reset to the upper bound impedance threshold value Z_{TH-Max}. The method 700 then transitions to operation 720. If the timer has not timed out (NO at operation 716), the method 700 transitions to operation 720.

At operation 720, the most recently set value of the enable/disable instruction may be provided to the current adjuster 312 (buffer 314) as the Audio_Enable_Buffer signal 324 to control the current adjuster 312 (buffer 314) to enable or disable the current adjuster 312 (buffer 314).

If the current adjuster 312 is enabled (e.g., if the impedance is less than the threshold Z_{TH}), the available current that may be delivered to the connected device(s) 250 may be increased. If the current adjuster 312 is disabled (e.g., if the impedance is greater than (or equal to) the threshold Z_{TH}), the available current deliverable to the connected device(s) 250 may be decreased. In an exemplary embodiment, the DSP 302 may enable the current adjuster 312 (e.g., enable buffer 314) to make additional current I_{CA} available/deliverable to the connected device(s) 250, or disable the current adjuster 312 (e.g., disable buffer 314) to no longer make the current I_{CA} available/deliverable to the connected device(s) 250.

After operation 720, the method 700 transitions to operation 722, where it may be determined whether the methods 500, 600, and 700 should be repeated. If so, the method 700 transitions to method 500 and operations 502 and 508 are performed again. Otherwise, the method 700 may end. The processing circuitry 212 (e.g. DSP 302) may determine if the methods 500, 600, 700 should be repeated (e.g., for a next sample).

The techniques of this disclosure may also be described in the following paragraphs.

An audio monitoring device may comprise an interface and processing circuitry. The interface may be configured to removably couple with an audio output device to establish an electrical coupling between the audio monitoring device and the audio output device. The processing circuitry may be configured to: provide an audio signal to the audio output device via the electrical coupling, determine an impedance of the audio output device, and adaptively adjust (e.g., based on the determined impedance of the audio output device) a current deliverable to the audio output device. The processing circuitry may comprise a first amplifier configured to provide the audio signal to the audio output device; and/or a second amplifier configured to selectively provide a first portion of the current deliverable to the audio output device. The processing circuitry may be configured to selectively enable the second amplifier to adaptively adjust the current deliverable to the audio output device. The selective enabling of the second amplifier may be based on the determined impedance. The first amplifier may be configured to provide a second portion of the current deliverable to the audio output device. The second amplifier may be configured to selectively provide the first portion of the current deliverable to the audio output device to adaptively adjust the current deliverable to the audio output device. The processing circuitry may comprise a processor, which may be configured to: determine a voltage output of the first amplifier deliverable to the audio output device, determine the current deliverable to the audio output device; and/or determine the impedance of the audio output device based on the determined voltage and the determined current. The processing circuitry may comprise a third amplifier that may be configured to determine a voltage differential across a resistor connected in series between an output of the first amplifier and the interface. The processing circuitry may be configured to determine the impedance of the audio output device based on the voltage differential. The processing circuitry may be configured to: determine a current delivered through the resistor; and/or determine the impedance of the audio output device based on the determined current through the resistor. The second amplifier may be connected in parallel between the first amplifier and the interface. The second amplifier may be a unity gain buffer. The processing circuitry may be configured to: determine a voltage deliverable to the audio output device; determine the current deliverable to the audio output device; and determine the impedance of the audio output device based on the determined voltage and the determined current. The processing circuitry may be configured to: increase the current deliverable to the audio output device in response to the determined impedance being less than an impedance threshold value, and/or decrease the current deliverable to the audio output device in response to the determined impedance being greater than the impedance threshold value. The processing circuitry may comprise a first amplifier configured to provide the audio signal to the audio output device. The processing circuitry may comprise a second amplifier connected in parallel between the first amplifier and the interface. The second amplifier may be configured to be selectively enabled to adaptively adjust the current deliverable to the audio output device. The selective enabling of second amplifier may be based on the determined impedance of the audio output device. The processing circuitry may comprise: a resistor connected in series between an output of the first amplifier and the interface. The processing circuitry may also comprise a third amplifier configured to determine a voltage differential across the resistor. The processing circuitry may be configured to determine the impedance of the audio output device based on the voltage differential. The processing circuitry may be configured to determine a current delivered through the resistor. The processing circuitry may be configured to determine the impedance of the audio output device based on the determined current through the resistor. The processing circuitry may comprise a voltage detector configured to detect a voltage deliverable to the audio output device. The processing circuitry may comprise a processor, which may be configured to determine the current deliverable to the audio output device based on the detected voltage. The processor may be configured to determine the impedance of the audio output device based on the detected voltage and the determined current.

A current adjustment method of an audio device may comprise determining a voltage deliverable by the audio device to a removably connected audio device; determining a current deliverable by the audio device to the removably connected audio device; determining an impedance of the removably connected audio device based on the determined voltage and the determined current; and adjusting the current deliverable to the removably connected audio device based on the determined impedance of the removably connected audio device. Adjusting the current deliverable to the removably connected audio device may comprise: comparing the determined impedance of the removably connected audio device to an impedance threshold value; increasing the current deliverable to the removably connected audio device in response to the determined impedance being less than the impedance threshold value; and decreasing the current deliverable to the removably connected audio device in response to the determined impedance being greater than the impedance threshold value. Adjusting the current deliverable to the removably connected audio device may comprise selectively enabling a current adjuster configured to generate a supplemental current. A primary current and the supplemental current may be components of the current deliverable to the removably connected audio device. Determining the current deliverable to the removably connected audio device may comprise detecting a voltage differential associated with the voltage deliverable to the removably connected audio device.

An apparatus may comprise an amplifier and a current adjuster. The amplifier may be configured to deliver a voltage and/or a current to a removably connected audio component. The current adjuster may be configured to selectively provide a supplemental current to the removably connected audio component (e.g., to adjust a total current deliverable to the removably connected audio component). The apparatus may include a digital signal processor that may be configured to: determine an impedance of the removably connected audio component based on the voltage and/or the current. The digital signal processor may be configured to control the current adjuster to provide the supplemental current to the removably connected audio component based on the determined impedance.

One or more aspects of the disclosure may be embodied in computer-usable data or computer-executable instructions, such as in one or more program modules, executed by one or more computers or other devices to perform the operations described herein. Generally, program modules include routines, programs, objects, components, data structures, and the like that perform particular tasks or implement particular abstract data types when executed by one or more processors in a computer or other data processing device. The computer-executable instructions may be stored as computer-readable instructions on a computer-readable medium such as a hard disk, optical disk, removable storage media, solid-state memory, RAM, and the like. The functionality of the program modules may be combined or distributed as desired in various embodiments. In addition, the functionality may be embodied in whole or in part in firmware or hardware equivalents, such as integrated circuits, application-specific integrated circuits (ASICs), field programmable gate arrays (FPGA), and the like. Particular data structures may be used to more effectively implement one or more aspects of the disclosure, and such data structures are contemplated to be within the scope of computer executable instructions and computer-usable data described herein.

Processing circuitry may include circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

Various aspects described herein may be embodied as a method, an apparatus, or as one or more computer-readable media storing computer-executable instructions. Accordingly, those aspects may take the form of an entirely hardware embodiment, an entirely software embodiment, an entirely firmware embodiment, or an embodiment combining software, hardware, and firmware aspects in any combination. In addition, various signals representing data or events as described herein may be transferred between a source and a destination in the form of light or electromagnetic waves traveling through signal-conducting media such as metal wires, optical fibers, or wireless transmission media (e.g., air or space). In general, the one or more computer-readable media may be and/or include one or more non-transitory computer-readable media.

As described herein, the various methods and acts may be operative across one or more computing servers and one or more networks. The functionality may be distributed in any manner, or may be located in a single computing device (e.g., a server, a client computer, and the like). For example, in alternative embodiments, one or more of the computing platforms discussed above may be combined into a single computing platform, and the various functions of each computing platform may be performed by the single computing platform. In such arrangements, any and/or all of the above-discussed communications between computing platforms may correspond to data being accessed, moved, modified, updated, and/or otherwise used by the single computing platform. Additionally, or alternatively, one or more of the computing platforms discussed above may be implemented in one or more virtual machines that are provided by one or more physical computing devices. In such arrangements, the various functions of each computing platform may be performed by the one or more virtual machines, and any and/or all of the above-discussed communications between computing platforms may correspond to data being accessed, moved, modified, updated, and/or otherwise used by the one or more virtual machines.

Aspects of the disclosure have been described in terms of illustrative embodiments thereof. Numerous other embodiments, modifications, and variations within the scope and spirit of the appended claims will occur to persons of ordinary skill in the art from a review of this disclosure. For example, one or more of the steps depicted in the illustrative figures may be performed in other than the recited order, and one or more depicted steps may be optional in accordance with aspects of the disclosure.

Hereinafter, various characteristics will be highlighted in a set of numbered clauses or paragraphs. These characteristics are not to be interpreted as being limiting on the invention or inventive concepts but are provided merely to highlight some characteristics as described herein, without suggesting a particular order of importance or relevancy of such characteristics.

Clause 1. An audio monitoring device comprising: an interface configured to removably couple with an audio output device to establish an electrical coupling between the audio monitoring device and the audio output device; and processing circuitry configured to: provide an audio signal to the audio output device via the electrical coupling; determine an impedance of the audio output device; and adaptively adjust, based on the determined impedance of the audio output device, a current deliverable to the audio output device.

Clause 2. The audio monitoring device of clause 1, wherein the processing circuitry comprises: a first amplifier configured to provide the audio signal to the audio output device; and a second amplifier configured to selectively provide a first portion of the current deliverable to the audio output device.

Clause 3. The audio monitoring device of clause 2, wherein the processing circuitry is configured to selectively enable, based on the determined impedance, the second amplifier to adaptively adjust the current deliverable to the audio output device.

Clause 4. The audio monitoring device of any of clauses 2-3, wherein: the first amplifier is further configured to provide a second portion of the current deliverable to the audio output device; and the second amplifier is configured to selectively provide the first portion of the current deliverable to the audio output device to adaptively adjust the current deliverable to the audio output device.

Clause 5. The audio monitoring device of any of clauses 2-4, wherein the processing circuitry comprises a processor configured to: determine a voltage output of the first amplifier deliverable to the audio output device; determine the current deliverable to the audio output device; and determine the impedance of the audio output device based on the determined voltage and the determined current.

Clause 6. The audio monitoring device of any of clauses 2-5, wherein the processing circuitry comprises a third amplifier configured to determine a voltage differential across a resistor connected in series between an output of the first amplifier and the interface, the processing circuitry being configured to determine the impedance of the audio output device based on the voltage differential.

Clause 7. The audio monitoring device of clause 6, wherein the processing circuitry is configured to: determine a current delivered through the resistor; and determine the impedance of the audio output device further based on the determined current through the resistor.

Clause 8. The audio monitoring device of any of clauses 2-7, wherein the second amplifier is connected in parallel between the first amplifier and the interface.

Clause 9. The audio monitoring device of any of clauses 2-8, wherein the second amplifier is a unity gain buffer.

Clause 10. The audio monitoring device of any of clauses 1-9, wherein the processing circuitry is configured to: determine a voltage deliverable to the audio output device; determine the current deliverable to the audio output device; and determine the impedance of the audio output device based on the determined voltage and the determined current.

Clause 11. The audio monitoring device of any of clauses 1-10, wherein the processing circuitry is configured to: increase the current deliverable to the audio output device in response to the determined impedance being less than an impedance threshold value; and decrease the current deliverable to the audio output device in response to the determined impedance being greater than the impedance threshold value.

Clause 12. The audio monitoring device of any of clauses 1-11, wherein the processing circuitry comprises: a first amplifier configured to provide the audio signal to the audio output device; and a second amplifier connected in parallel between the first amplifier and the interface, and configured to be selectively enabled, based on the determined impedance of the audio output device, to adaptively adjust the current deliverable to the audio output device.

Clause 13. The audio monitoring device of clause 12, wherein the processing circuitry further comprises: a resistor connected in series between an output of the first amplifier and the interface; and a third amplifier configured to determine a voltage differential across the resistor, the processing circuitry being configured to determine the impedance of the audio output device based on the voltage differential.

Clause 14. The audio monitoring device of clause 13, wherein the processing circuitry is configured to: determine a current delivered through the resistor; and determine the impedance of the audio output device further based on the determined current through the resistor.

Clause 15. The audio monitoring device of any of clauses 1-14, wherein the processing circuitry comprises: a voltage detector configured to detect a voltage deliverable to the audio output device; and a processor configured to determine the current deliverable to the audio output device based on the detected voltage; and determine the impedance of the audio output device based on the detected voltage and the determined current.

Clause 16. A current adjustment method of an audio device, comprising: determining a voltage deliverable by the audio device to a removably connected audio device; determining a current deliverable by the audio device to the removably connected audio device; determining an impedance of the removably connected audio device based on the determined voltage and the determined current; and adjusting the current deliverable to the removably connected audio device based on the determined impedance of the removably connected audio device.

Clause 17. The current adjustment method of clause 16, wherein adjusting the current deliverable to the removably connected audio device comprises: comparing the determined impedance of the removably connected audio device to an impedance threshold value; increasing the current deliverable to the removably connected audio device in response to the determined impedance being less than the impedance threshold value; and decreasing the current deliverable to the removably connected audio device in response to the determined impedance being greater than the impedance threshold value.

Clause 18. The current adjustment method of any of clauses 16-17, wherein adjusting the current deliverable to the removably connected audio device comprises selectively enabling a current adjuster configured to generate a supplemental current, a primary current and the supplemental current being components of the current deliverable to the removably connected audio device.

Clause 19. The current adjustment method of any of clauses 16-18, wherein determining the current deliverable to the removably connected audio device comprises detecting a voltage differential associated with the voltage deliverable to the removably connected audio device.

Clause 20. An apparatus comprising: an amplifier configured to deliver a voltage and a current to a removably connected audio component; a current adjuster configured to selectively provide a supplemental current to the removably connected audio component to adjust a total current deliverable to the removably connected audio component; and a digital signal processor configured to: determine an impedance of the removably connected audio component based on the voltage and the current; and control the current adjuster to provide the supplemental current to the removably connected audio component based on the determined impedance.

Clause 21. An audio monitoring device comprising: interfacing means for removably coupling with an audio output device to establish an electrical coupling between the audio monitoring device and the audio output device; and processing means for: providing an audio signal to the audio output device via the electrical coupling; determining an impedance of the audio output device; and adaptively adjusting, based on the determined impedance of the audio output device, a current deliverable to the audio output device.

Clause 22. The audio monitoring device of clause 21, wherein the processing means comprises: a first amplifying means for providing the audio signal to the audio output device; and a second amplifying means for selectively providing a first portion of the current deliverable to the audio output device.

Clause 23. The audio monitoring device of clause 22, wherein the processing means is configured to selectively enable, based on the determined impedance, the second amplifying means for adaptively adjusting the current deliverable to the audio output device.

Clause 24. The audio monitoring device of any of clauses 22-23, wherein: the first amplifying means is further configured for providing a second portion of the current deliverable to the audio output device; and the second amplifying means is configured for selectively providing the first portion of the current deliverable to the audio output device to adaptively adjust the current deliverable to the audio output device.

Clause 25. The audio monitoring device of any of clauses 22-24, wherein the processing means comprises a processor configured to: determine a voltage output of the first amplifying means deliverable to the audio output device; determine the current deliverable to the audio output device; and determine the impedance of the audio output device based on the determined voltage and the determined current.

Clause 26. The audio monitoring device of any of clauses 22-25, wherein the processing means comprises a third amplifying means for determining a voltage differential across a resistance means connected in series between an output of the first amplifying means and the interfacing means, the processing means being configured to determine the impedance of the audio output device based on the voltage differential.

Clause 27. The audio monitoring device of clause 26, wherein the processing means is configured for: determining a current delivered through the resistance means; and determining the impedance of the audio output device further based on the determined current through the resistance means.

Clause 28. The audio monitoring device of any of clauses 22-27, wherein the second amplifying means is connected in parallel between the first amplifying means and the interfacing means.

Clause 29. The audio monitoring device of any of clauses 22-28, wherein the second amplifying means is a unity gain buffer.

Clause 30. The audio monitoring device of any of clauses 21-29, wherein the processing means is configured for: determining a voltage deliverable to the audio output device; determining the current deliverable to the audio output device; and determining the impedance of the audio output device based on the determined voltage and the determined current.

Clause 31. The audio monitoring device of any of clauses 21-30, wherein the processing means is configured for: increasing the current deliverable to the audio output device in response to the determined impedance being less than an impedance threshold value; and decreasing the current deliverable to the audio output device in response to the determined impedance being greater than the impedance threshold value.

32. The audio monitoring device of any of clauses 21-31, wherein the processing means comprises: a first amplifying means for providing the audio signal to the audio output device; and a second amplifying means connected in parallel between the first amplifying means and the interfacing means, and configured to be selectively enabled, based on the determined impedance of the audio output device, for adaptively adjusting the current deliverable to the audio output device.

Clause 33. The audio monitoring device of clause 32, wherein the processing means further comprises: a resistance means connected in series between an output of the first amplifying means and the interfacing means; and a third amplifying means for determining a voltage differential across the resistance means, the processing means being configured for determining the impedance of the audio output device based on the voltage differential.

Clause 34. The audio monitoring device of clause 33, wherein the processing means is configured for: determining a current delivered through the resistance means; and determining the impedance of the audio output device further based on the determined current through the resistance means.

Clause 35. The audio monitoring device of any of clauses 21-34, wherein the processing means comprises: voltage detecting means for detecting a voltage deliverable to the audio output device; and a processor configured to: determine the current deliverable to the audio output device based on the detected voltage; and determine the impedance of the audio output device based on the detected voltage and the determined current.

Clause 36. An apparatus comprising: amplifying means for delivering a voltage and a current to a removably connected audio component; current adjusting means for selectively providing a supplemental current to the removably connected audio component to adjust a total current deliverable to the removably connected audio component; and processing means for: determining an impedance of the removably connected audio component based on the voltage and the current; and controlling the current adjusting means to provide the supplemental current to the removably connected audio component based on the determined impedance.

Clause 37. One or more non-transitory media storing instructions that, when executed by one or more processors, cause the one or more processors to perform the method of any of clauses 16-19.

Clause 38. An apparatus comprising: one or more processors; and memory storing instructions that, when executed by the one or more processors, cause the apparatus to perform the method of any of clauses 16-19.

1. An audio monitoring device comprising:
an interface configured to removably couple with an audio output device to establish an electrical coupling between the audio monitoring device and the audio output device; and
processing circuitry configured to:
provide an audio signal to the audio output device via the electrical coupling;
determine an impedance of the audio output device; and
adaptively adjust, based on the determined impedance of the audio output device, a current deliverable to the audio output device.

2. The audio monitoring device of claim 1, wherein the processing circuitry comprises:
a first amplifier configured to provide the audio signal to the audio output device; and
a second amplifier configured to selectively provide a first portion of the current deliverable to the audio output device.

3. The audio monitoring device of claim 2, wherein the processing circuitry is configured to selectively enable, based on the determined impedance, the second amplifier to adaptively adjust the current deliverable to the audio output device.

4. The audio monitoring device of claim 2, wherein:
the first amplifier is further configured to provide a second portion of the current deliverable to the audio output device; and
the second amplifier is configured to selectively provide the first portion of the current deliverable to the audio output device to adaptively adjust the current deliverable to the audio output device.

5. The audio monitoring device of claim 2, wherein the processing circuitry comprises a processor configured to:
determine a voltage output of the first amplifier deliverable to the audio output device;
determine the current deliverable to the audio output device; and
determine the impedance of the audio output device based on the determined voltage and the determined current.

6. The audio monitoring device of claim 2, wherein the processing circuitry comprises a third amplifier configured to determine a voltage differential across a resistor connected in series between an output of the first amplifier and the interface, the processing circuitry being configured to determine the impedance of the audio output device based on the voltage differential.

7. The audio monitoring device of claim 6, wherein the processing circuitry is configured to:
determine a current delivered through the resistor; and
determine the impedance of the audio output device further based on the determined current through the resistor.

8. The audio monitoring device of claim 2, wherein the second amplifier is connected in parallel between the first amplifier and the interface.

9. The audio monitoring device of claim 2, wherein the second amplifier is a unity gain buffer.

10. The audio monitoring device of claim 2, wherein the processing circuitry is configured to:
determine a voltage deliverable to the audio output device;
determine the current deliverable to the audio output device; and
determine the impedance of the audio output device based on the determined voltage and the determined current.

11. The audio monitoring device of claim 1, wherein the processing circuitry is configured to:
increase the current deliverable to the audio output device in response to the determined impedance being less than an impedance threshold value; and
decrease the current deliverable to the audio output device in response to the determined impedance being greater than the impedance threshold value.

12. The audio monitoring device of claim 1, wherein the processing circuitry comprises:
a first amplifier configured to provide the audio signal to the audio output device; and
a second amplifier connected in parallel between the first amplifier and the interface, and configured to be selectively enabled, based on the determined impedance of the audio output device, to adaptively adjust the current deliverable to the audio output device.

13. The audio monitoring device of claim 12, wherein the processing circuitry further comprises:
a resistor connected in series between an output of the first amplifier and the interface; and
a third amplifier configured to determine a voltage differential across the resistor, the processing circuitry being configured to determine the impedance of the audio output device based on the voltage differential.

14. The audio monitoring device of claim 13, wherein the processing circuitry is configured to:
determine a current delivered through the resistor; and
determine the impedance of the audio output device further based on the determined current through the resistor.

15. The audio monitoring device of claim 1, wherein the processing circuitry comprises:
a voltage detector configured to detect a voltage deliverable to the audio output device; and
a processor configured to determine the current deliverable to the audio output device based on the detected voltage; and
determine the impedance of the audio output device based on the detected voltage and the determined current.

16. A current adjustment method of an audio device, comprising:
determining a voltage deliverable by the audio device to a removably connected audio device;
determining a current deliverable by the audio device to the removably connected audio device;
determining an impedance of the removably connected audio device based on the determined voltage and the determined current; and
adjusting the current deliverable to the removably connected audio device based on the determined impedance of the removably connected audio device.

17. The current adjustment method of claim 16, wherein adjusting the current deliverable to the removably connected audio device comprises:
comparing the determined impedance of the removably connected audio device to an impedance threshold value;
increasing the current deliverable to the removably connected audio device in response to the determined impedance being less than the impedance threshold value; and
decreasing the current deliverable to the removably connected audio device in response to the determined impedance being greater than the impedance threshold value.

18. The current adjustment method of claim 16, wherein adjusting the current deliverable to the removably connected audio device comprises selectively enabling a current adjuster configured to generate a supplemental current, a primary current and the supplemental current being components of the current deliverable to the removably connected audio device.

19. The current adjustment method of claim 16, wherein determining the current deliverable to the removably connected audio device comprises detecting a voltage differential associated with the voltage deliverable to the removably connected audio device.

20. An apparatus comprising:
an amplifier configured to deliver a voltage and a current to a removably connected audio component;
a current adjuster configured to selectively provide a supplemental current to the removably connected audio component to adjust a total current deliverable to the removably connected audio component; and
a digital signal processor configured to:
determine an impedance of the removably connected audio component based on the voltage and the current; and
control the current adjuster to provide the supplemental current to the removably connected audio component based on the determined impedance.
